(19) United States
(12) Patent Application Publication
(10) Pub. No.: US 2015/0361547 A1
(43) Pub. Date: Dec. 17, 2015

(54) METHOD AND APPARATUS FOR CLEANING CHEMICAL VAPOR DEPOSITION CHAMBER

(71) Applicant: Taiwan Semiconductor Manufacturing Co., Ltd, Hsin-Chu (TW)

(72) Inventors: Min-Hui LIN, Tainan City (TW); Kuo-Hsien CHENG, Tainan City (TW); Chia-Hsing CHOU, Tainan City (TW); Miao-Cheng LIAO, Tsztung Shiang (TW); Lai-Wan CHONG, Kaohsiung City (TW)

(21) Appl. No.: 14/303,819

(22) Filed: Jun. 13, 2014

(51) Int. Cl. C23C 16/44; B08B 9/00; B08B 7/00; C23C 16/50

(52) U.S. Cl. CPC C23C 16/4405; C23C 16/50; B08B 9/00; B08B 7/0035

(57) ABSTRACT

A method and an apparatus for forming a cleaning a chemical vapor deposition (CVD) chamber are provided. The method includes providing a chemical vapor deposition (CVD) chamber. The method further includes introducing a remote plasma source into the CVD chamber. The method also includes performing a plasma cleaning process to the CVD chamber by applying a radio-frequency (RF) power in the CVD chamber.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon.

In forming multi-level integrated circuit devices, a major portion of the manufacturing cycle involves chemical vapor deposition (CVD), to deposit material layers. In particular, the depositing of oxide insulating layers, such as inter-metal dielectric (IMD) layers, is performed several times in the formation of a multi-level integrated circuit device. A film is formed not only on a substrate but also on inner walls of a CVD chamber. In addition, the chemical byproducts and unwanted reagents of such deposition processes are mostly exhausted from the chamber by an exhaust pump, but some residue is unavoidably deposited on the inner walls of the chamber. Thus, the CVD chamber is cleaned periodically to remove unwanted films or residues on the inner walls of the CVD chamber.

Although existing cleaning methods have been generally adequate for their intended purpose, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a simplified schematic representation of a chemical vapor deposition (CVD) chamber cleaning apparatus.

FIG. 2 shows a flow-chart of a method for cleaning a CVD chamber, in accordance with some embodiments.

FIG. 3 shows a flow-chart of a method for cleaning a CVD chamber, in accordance with some embodiments.

FIG. 4 shows a plot illustrating the effect of a hybrid cleaning method, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some variations of the embodiments are described. Throughout the various views and illustrative embodiments, like reference numbers are used to designate like elements. It is understood that additional operations can be provided before, during, and after the method, and some of the operations described can be replaced or eliminated for other embodiments of the method.

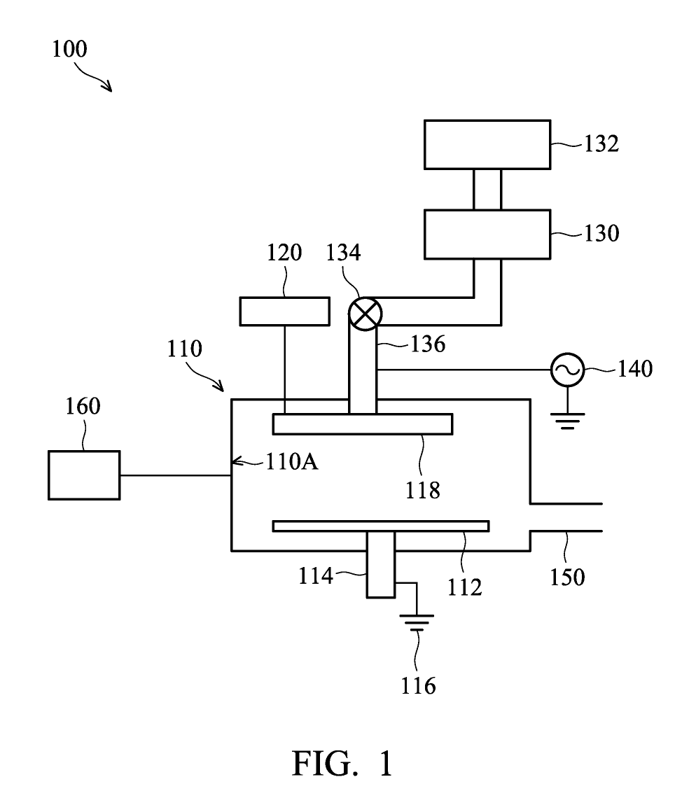

Embodiments of an apparatus and method for cleaning a chemical vapor deposition (CVD) chamber are provided. FIG. 1 shows a simplified schematic representation of a chemical vapor deposition (CVD) chamber cleaning apparatus 100.

As shown in FIG. 1, chemical vapor deposition (CVD) chamber cleaning apparatus 100 includes a chamber 110. Chamber 110 includes wall portions, e.g. 110A. In some embodiments, chemical byproducts and unwanted reagents form on wall portions 110A. Chamber 110 further includes a wafer support 112, a pedestal 114, grounding 116, and a shower head 118. Wafer support 112 is configured to hold a process wafer (not shown). In some embodiments, wafer support 112 is an electrostatic chuck. In some embodiments, a temperature regulator is formed in wafer support 112 to regulate the temperature of a substrate placed thereon. Pedestal 114 is configured to support wafer support 112.

Shower head 118 and wafer support 112 are arranged in parallel and facing each other inside chamber 110, and shower head 118 serves as an upper electrode, wafer support 112 serves as a lower electrode. A radio frequency (RF) generator 120 is configured to apply RF power to shower head 118 and wafer support 112, and a plasma is excited between shower head 118 and wafer support 112.

A remote plasma generator 130 outside chamber 110 is connected to chamber 110 via a valve 134 and a piping 136. Cleaning source 132 is connected to remote plasma generator 130, and it is configured to supply the cleaning gas into remote plasma generator 130. In addition, a gas flow controller 140 is connected to piping 136. Gas flow controller 140 is configured to measure the flow rate of gas.

Cleaning source 132 supplies the cleaning gas including fluorine-containing gas, inert gas or combinations thereof. The fluorine-containing gas comprises nitrogen trifluoride (NF₃), hexafluoroethane (C₂F₆), tetrafluoromethane (CF₄), fluoroform (CHF₃), fluorine (F₂), hydrogen fluoride (HF) or combinations thereof. The inert gas comprises argon (Ar), helium (He), neon (Ne), krypton (Kr), xenon (Xe) or combinations thereof. In some embodiments, a gas mixture containing radicals is produced by a plasma decomposition of the fluorine-containing gas.

An exhaust outlet 150 is connected to chamber 110. The chemical byproducts and unwanted reagents from chamber 110 are exhausted by exhaust outlet 150.

Controller system 160 is coupled to chamber 110. Controller system 160 is configured to control process condition during the plasma cleaning process. In some embodiments, controller system 160 includes one or more memory devices and one or more processors. It should be noted that a process wafer is not present during the plasma cleaning process.

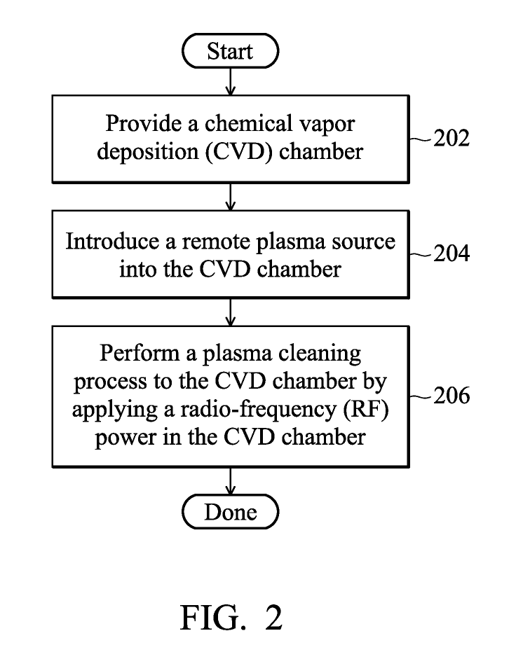

FIG. 2 shows a flow-chart of a method for cleaning a CVD chamber, in accordance with some embodiments.

In operation 202, a CVD chamber is provided. In some embodiments, CVD chamber 110 is provided, as shown in FIG. 1.

In operation 204, a remote plasma source is introduced into the CVD chamber (e.g. CVD chamber 110). In some embodiments, as shown in FIG. 1, the cleaning gas is supplied from cleaning source 132 into remote plasma generator 130, and the cleaning gas is excited to form the remote plasma source. The cleaning gas may be excited by RF power. For example, the fluorine radicals are produced by exciting nitrogen trifluoride (NF₃). In particular, the radicals are used to remove resides containing silicon, silicon oxide or silicon nitride. The residues are formed by processes such as a cleaning chemical vapor deposition process.

In some embodiments, the remote plasma source includes inert gas and fluorine-containing gas with a volume ratio in a range from about 1/1 to about 10/1. In some embodiments, the remote plasma source includes argon and nitrogen trifluoride (NF₃) with a volume ratio in a range from about 1/1 to about 10/1.

In some embodiments, the flow rate of argon is in a range from about 500 sccm to about 30000 sccm, and the flow rate of nitrogen trifluoride (NF₃) is in a range from about 500 sccm to about 5000 sccm. If the flow rate is too high, the gas is wasted and uniformity of gas is bad. If the flow rate is too low, cleaning efficiency is bad.

In operation 206, a plasma cleaning process is performed to the CVD chamber (e.g. CVD chamber 100) by applying a RF power in the CVD chamber. In some embodiments, as shown in FIG. 1, the RF power is generated from RF generator 120, and it is applied to shower head 118 and wafer support 112 to form an in-situ plasma in the interior of CVD chamber 100. In addition, the CVD chamber (e.g. CVD chamber 100) may be heated up to improve cleaning efficiency.

It should be noted that, in remote plasma generator 130, the cleaning gas is activated to form cleaning radicals, and the cleaning radicals are more reactive than the original cleaning gas. Therefore, remote plasma generator 130 provides a high degree of dissociation of the radicals of the cleaning gas. However, many of these radicals are in unstable states, and thus they may go back to their stable states, such as recombination of radicals back into molecules, before reaching CVD chamber 110.

In order to improve the dissociation degree of the cleaning gas, an in-situ plasma process is performed to CVD chamber 110. The molecules that have already recombined or have not dissociated in remote plasma generator 130 may be activated by the in-situ plasma process. As a result, the concentration of the radicals is increased by the in-situ plasma process.

Although the cleaning efficiency is increased as the RF power is increased. The high RF power (e.g. greater than 1000 Watt) may damage the CVD chamber. Therefore, there is a trade off between the RF power and the dissociation degree of the cleaning gas. In some embodiments, the RF power is in a range from about 50 Watt to about 950 Watt. If the RF power is too high, the CVD chamber may be damaged. If the RF power is too low, the dissociation degree is too low to improve the cleaning efficiency.

In some embodiments, the plasma cleaning process is performed in a temperature in a range from about 0° C. to about 800° C. In some embodiments, the plasma cleaning process has an operation time in a range from about 10 seconds to about 300 seconds. In some embodiments, the plasma cleaning process has an operation pressure in a range from about 0.5 Torr to about 6 Torr. If the operation pressure is too high, the uniformity of the cleaning process is bad, and the CVD chamber is easily damaged. If the operation pressure is too low, the cleaning efficiency is bad, and the cleaning gas is wasted.

A hybrid cleaning process is provided by introducing a remote plasma source into a chemical vapor deposition (CVD) chamber, and in-situ applying radio-frequency (RF) power in the CVD chamber to perform a plasma cleaning process, in accordance with some embodiments. One advantage of the dissociation degree of the cleaning gas being increased is that the usage of fluorine-containing gas is reduced, and manufacturing costs for cleaning process are further reduced. Other advantages are that the cleaning efficiency is improved, and subsequent deposited CVD film uniformity is also improved.

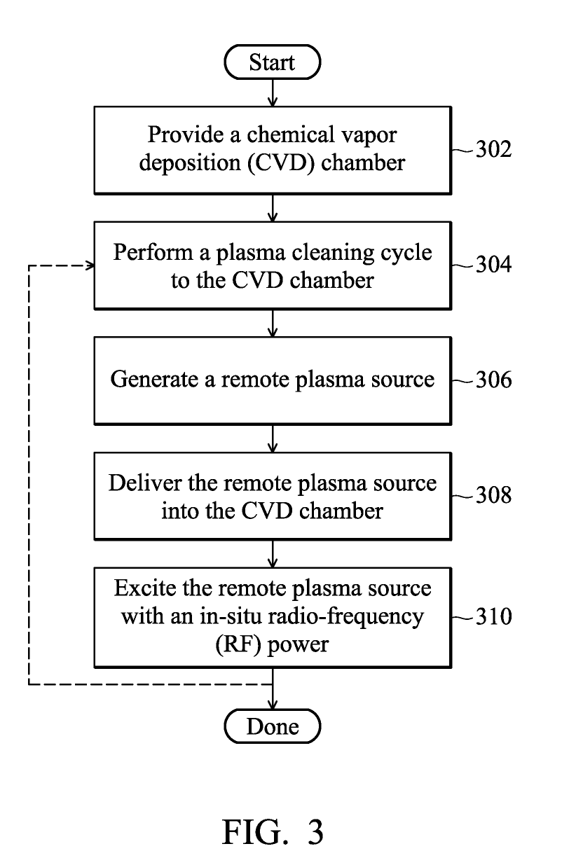

FIG. 3 shows a flow-chart of a method for cleaning a CVD chamber, in accordance with some embodiments.

In operation 302, a CVD chamber is provided. In some embodiments, CVD chamber 110 is provided, as shown in FIG. 1.

In operation 304, a plasma cleaning cycle is performed to the CVD chamber (e.g. CVD chamber 110). The plasma cleaning cycle includes repeating the following operations 304-310 until the CVD chamber is cleaned.

In operation 306, a remote plasma source is generated. In some embodiments, as shown in FIG. 1, the cleaning gas is supplied from cleaning source 132 into remote plasma generator 130, and the cleaning gas is excited to form the remote plasma source.

In operation 308, after remote plasma source is generated, the remote plasma source is delivered into the CVD chamber. In some embodiments, the remote plasma source is delivered into CVD chamber 110 via valve 134 and piping 136.

In operation 310, after the remote plasma source is delivered into the CVD chamber, the remote plasma source is excited by in-situ RF power. In some embodiments, the RF power is applied to shower head 118 and wafer support 112 by RF generator 120, and the plasma is excited between shower head 118 and wafer support 112. In some embodiments, if the CVD chamber is not clean enough, the CVD chamber is cleaned again by repeating the plasma cleaning cycle including operations 306, 308 and 310.

It should be noted that the in-situ RF power is configured to improve the dissociation degree of the remote plasma source. More radicals are produced by re-activated the remote plasma source, and therefore more residues are removed by the radicals.

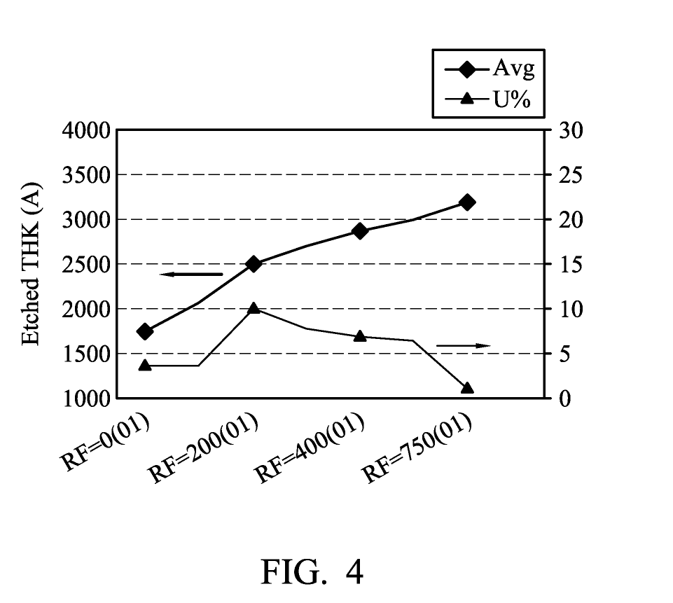

FIG. 4 shows a plot illustrating the effect of a hybrid cleaning method, in accordance with some embodiments. A silicon wafer is disposed on wafer support 112 of CVD chamber 110. Afterwards, a method of FIG. 2 or FIG. 3 is performed to measure the etched thickness and cleaning uniformity of the silicon wafer. The etched thickness is used to show the cleaning efficiency.

Table 1 shows the parameters of Embodiments 1-4 used in CVD chamber 110. FIG. 4 shows a plot illustrating the effect of a hybrid cleaning method, in accordance with some embodiments. As shown in FIG. 4, the right side of Y-axis shows the etching uniformity in the CVD chamber, and the left side of Y-axis shows the etched thickness. The X-axis shows the RF power of Embodiments 1-4.

TABLE 1

| | | Operation | | | |
|---|---|---|---|---|---|
| | RF | time of RF | operation | Flow rate | |
| embodi- | power | power | pressure | Ratio (Ar/NF₃) | Temperature |
| ments | (Watt) | (second) | (Torr) | (sccm/sccm) | (° C.) |
| 1 | 0 | 60 | 3.5 | 6000/1500 | 400 |
| 2 | 200 | 60 | 3.5 | 6000/1500 | 400 |
| 3 | 400 | 60 | 3.5 | 6000/1500 | 400 |
| 4 | 750 | 60 | 3.5 | 6000/1500 | 400 |

As shown in FIG. 4, the etched thickness of the silicon wafer is increased with an increase of RF power. In addition, the cleaning uniformity of the silicon wafer at 750 Watt is higher than that at 200 Watt or 400 Watt.

Although the cleaning efficiency is proportional to the RF power, the high RF power (e.g. larger than 1000 Watt) may damage the CVD chamber. Therefore, the RF power should be controlled in a range to avoid causing damage. In some embodiments, the RF power is in a range from about 50 Watt to about 950 Watt.

Embodiments for cleaning chemical vapor deposition (CVD) chamber are provided. A hybrid cleaning process is provided by introducing a remote plasma source into a CVD chamber, and in-situ applying a RF power in the CVD chamber to perform a plasma cleaning process. The dissociation degree of the remote plasma source is improved by increasing the RF power. The RF power should not be too high to avoid damaging the CVD chamber. Because the dissociation degree of the cleaning gas is increased, the usage of fluorine-containing gas is reduced, and manufacturing costs for the cleaning process are further reduced. Furthermore, the efficiency of the cleaning process is improved, and subsequent deposited CVD film uniformity is also improved.

In some embodiments, a method for cleaning a chemical vapor deposition (CVD) chamber is provided. The method includes providing a chemical vapor deposition (CVD) chamber. The method further includes introducing a remote plasma source into the CVD chamber. The method also includes performing a plasma cleaning process to the CVD chamber by applying a radio-frequency (RF) power on the CVD chamber.

In some embodiments, a method for cleaning chemical vapor deposition (CVD) chamber is provided. The method includes providing a chemical vapor deposition (CVD) chamber. The method also includes performing a plasma cleaning cycle on the CVD chamber by the operations of: generating a remote plasma source; delivering the remote plasma source into the CVD chamber; and exciting the remote plasma source with an in-situ radio-frequency (RF) power, and the in-situ RF power is configured to improve the dissociation degree of the remote plasma source.

In some embodiments, an apparatus for cleaning chemical vapor deposition (CVD) chamber is provided. The apparatus includes a chemical vapor deposition (CVD) chamber. The apparatus also includes a remote plasma generator outside the CVD chamber, and the remote plasma generator is configured to generate a remote plasma source. The apparatus further includes a radio-frequency (RF) power disposed in the CVD chamber, and the RF power is configured to excite the remote plasma source.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for cleaning chemical vapor deposition (CVD) chamber, comprising:
providing a chemical vapor deposition (CVD) chamber;
introducing a remote plasma source into the CVD chamber; and
performing a plasma cleaning process to the CVD chamber by applying a radio-frequency (RF) power in the CVD chamber.

2. The method for cleaning chemical vapor deposition (CVD) chamber as claimed in claim 1, wherein the remote plasma source comprises fluorine-containing gas, inert gas or combinations thereof.

3. The method for cleaning chemical vapor deposition (CVD) chamber as claimed in claim 2, wherein the fluorine-containing gas comprises nitrogen trifluoride (NF₃), hexafluoroethane (C₂F₆), tetrafluoromethane (CF₄), fluoroform (CHF₃), fluorine (F₂), hydrogen fluoride (HF) or combinations thereof.

4. The method for cleaning chemical vapor deposition (CVD) chamber as claimed in claim 2, wherein the inert gas comprises argon (Ar), helium (He), neon (Ne), krypton (Kr), xenon (Xe) or combinations thereof.

5. The method for cleaning chemical vapor deposition (CVD) chamber as claimed in claim 2, wherein the remote plasma source comprises inert gas and fluorine-containing gas with a volume ratio in a range from about 1/1 to about 10/1.

6. The method for cleaning chemical vapor deposition (CVD) chamber as claimed in claim 1, wherein the radio-frequency (RF) power is in a range from about 50 Watt to about 950 Watt.

7. The method for cleaning chemical vapor deposition (CVD) chamber as claimed in claim 1, wherein the plasma cleaning process is performed in a temperature in a range from about ° C. to about 800° C.

8. The method for cleaning chemical vapor deposition (CVD) chamber as claimed in claim 1, wherein an operation time of the plasma cleaning process is performed is in a range from about 10 seconds to about 300 seconds.

9. The method for cleaning chemical vapor deposition (CVD) chamber as claimed in claim 1, wherein performing the plasma cleaning process to the CVD chamber comprises the remote plasma source being excited with the RF power, wherein the RF power is configured to improve the dissociation rate of the remote plasma source.

10. The method for cleaning chemical vapor deposition (CVD) chamber as claimed in claim 1, wherein the CVD chamber comprises plasma-enhanced CVD (PECVD), high density plasma CVD (HDP-CVD), remote plasma (RP CVD), metal organic CVD (MOCVD) or downstream plasma chamber.

11. A method for cleaning chemical vapor deposition (CVD) chamber, comprising:
providing a chemical vapor deposition (CVD) chamber; and
performing a plasma cleaning cycle to the CVD chamber by the operations of:
generating a remote plasma source;
delivering the remote plasma source into the CVD chamber; and
exciting the remote plasma source with an in-situ radio-frequency (RF) power, wherein the in-situ RF power is configured to improve the dissociation degree of the remote plasma source.

12. The method for cleaning chemical vapor deposition (CVD) chamber as claimed in claim 1, wherein the radio-frequency (RF) power is in a range from about 50 Watt to about 950 Watt.

13. The method for cleaning chemical vapor deposition (CVD) chamber as claimed in claim 1, wherein the remote plasma source comprises fluorine-containing gas, inert gas or combinations thereof.

14. The method for cleaning chemical vapor deposition (CVD) chamber as claimed in claim 13, wherein the in-situ RF power is configured to improve the dissociation rate of fluorine-containing gas of the remote plasma source.

15. The method for cleaning chemical vapor deposition (CVD) chamber as claimed in claim 13, wherein the fluorine-containing gas comprises nitrogen trifluoride (NF₃), hexafluoroethane (C₂F₆), tetrafluoromethane (CF₄), fluoroform (CHF₃), fluorine (F₂), hydrogen fluoride (HF) or combinations thereof.

16. The method for cleaning chemical vapor deposition (CVD) chamber as claimed in claim 13, wherein the inert gas comprises argon (Ar), helium (He), neon (Ne), krypton (Kr), xenon (Xe) or combinations thereof.

17. The method for cleaning chemical vapor deposition (CVD) chamber as claimed in claim 13, the inert gas and fluorine-containing gas have a volume ratio in a range from about 1/1 to about 10/1.

18. A apparatus for cleaning a chemical vapor deposition (CVD) chamber, comprising:
a chemical vapor deposition (CVD) chamber;
a remote plasma generator outside the CVD chamber, wherein the remote plasma generator is configured to generate a remote plasma source;
a radio-frequency (RF) power disposed in the CVD chamber, wherein the RF power is configured to excite the remote plasma source.

19. The apparatus for cleaning a chemical vapor deposition (CVD) chamber as claimed in claim 18, further comprising:
an upper electrode and a lower electrode disposed in the CVD chamber, wherein the RF power is applied to the upper electrode and the lower electrode.

20. The apparatus for cleaning a chemical vapor deposition (CVD) chamber as claimed in claim 18, further comprising:
a cleaning source disposed outside the CVD chamber, wherein the source is configured to supply a cleaning gas into the remote plasma generator.
